(19) United States
(12) Patent Application Publication
(10) Pub. No.: US 2021/0265199 A1
(43) Pub. Date: Aug. 26, 2021

(54) SEMICONDUCTOR DEVICE AND FABRICATING METHOD THEREOF

(71) Applicant: Changxin Memory Technologies, Inc., Hefei (CN)

(72) Inventors: Ping-Heng WU, HEFEI (CN); Dingyou LIN, HEFEI (CN)

(21) Appl. No.: 17/318,210

(22) Filed: May 12, 2021

Related U.S. Application Data
(63) Continuation of application No. PCT/CN2019/118462, filed on Nov. 14, 2019.

(30) Foreign Application Priority Data
Nov. 16, 2018 (CN) 201811369379.8
Nov. 16, 2018 (CN) 201821896656.6

(51) Int. Cl. H01L 21/762; H01L 27/092

(52) U.S. Cl. CPC H01L 21/76232; H01L 27/092

(57) ABSTRACT

A semiconductor device and a method of fabricating the same are disclosed. The semiconductor device includes: a semiconductor substrate including island patterns and trenches alternately arranged in a semiconductor substrate, wherein an upper surface of the island pattern close to a corresponding one of the trenches is a corner area; a patterned liner oxide layer covering an area of the upper surface of the island pattern except the corner area; and a protective layer covering the sidewalls and the bottom surface of the trench, the corner area and the side surface of the patterned liner oxide layer, wherein the protective layer extends from the sidewall of the trench to the corner area to form a corner; and an isolation structure located within each of the trenches. An area of the island pattern near the corner may be prevented from being oxidized.

### CROSS-REFERENCE TO RELATED APPLICATIONS

This application is a continuation application of International Patent Application No. PCT/CN2019/118462, filed on Nov. 14, 2019, which is based on and claims priority of the Chinese Patent Applications No. 201811369379.8 and 201821896656.6, both filed on Nov. 16, 2018. The above-referenced applications are incorporated herein by reference in their entirety.

### TECHNICAL FIELD

This present invention relates to the field of semiconductor technology and more specifically, but not by way of limitation, to a semiconductor device and a method of fabricating the same.

### BACKGROUND

The active area (AA region) of a semiconductor is an oxidized local region after etching a silicon nitride mask (i.e., an iso-silicon nitride).

In a conventional processing process, an active region is first defined by a trench formed by etching. Then a liner is formed on a sidewall of the trench to protect the sidewall of the active region, and finally the trench is filled with a filling material to form a shallow trench isolation (STI). The liner may, during an oxidation of a precursor of the STI, prevent the precursor from inadvertently oxidizing the active region on a corner junction between the sidewall and the upper surface of the active area, and oxidizing a portion of the STI near the corner junction. The precursor may be formed by Spin On Dielectric (SOD) or Flowable Chemical Vapor Deposition (Flowable CVD or FCVD, a fourth generation CVD technology). However, the corner junction of the active region and the portion of the STI near the corner junction are susceptible to oxidation reactions, and may be etched away during a subsequent removal of an oxide layer on the active region, which may result in a notch being formed at the corners of the active region and a portion of the STI near the corner junction.

Therefore, the conventional technical solutions still need to be improved.

It is to be noted that the information disclosed in this Background section is only for facilitating the understanding of the background of the invention and therefore may contain information that does not form the prior art that is already known to a person of ordinary skill in the art.

### SUMMARY

In view of the limitations of existing technologies described above, the present invention provides a semiconductor device and a semiconductor device fabricating method that overcome at least some of the aforementioned limitations, including a notch being formed at the corners of the active area.

One aspect of the present invention is directed to a method of fabricating a semiconductor device. The method may include: providing a semiconductor substrate; depositing a surface oxide layer and a hard mask on the semiconductor substrate; patterning the hard mask to form a patterned hard mask by performing a patterning process; patterning the surface oxide layer to form a patterned liner oxide layer; forming alternately arranged island patterns and trenches in the semiconductor substrate. A portion of an upper surface of each island pattern close to a corresponding one of the trenches may be a corner area, the patterned liner oxide layer may cover the island patterns, and the patterned hard mask may cover the patterned liner oxide layer.

The method may further include: performing lateral etching on a side surface of the patterned liner oxide layer to expose the corner area; forming a protective layer on a sidewall and a bottom surface of each of the trenches, the corner area, and a laterally etched side surface of the patterned liner oxide layer; and forming an isolation structure in the corresponding one of trenches. The protective layer may extend from the sidewall of each of the trenches to the upper surface of a corresponding one of the island patterns to form a corner.

In some embodiments of the present invention, each of the island patterns may be an active region in the semiconductor device.

In some embodiments of the present invention, the protective layer may be made of silicon oxide, silicon nitride, silicon oxynitride or silicon carbonitride.

In some embodiments of the present invention, the corner may have an angle in a range of 90 to 120 degrees.

In some embodiments of the present invention, the corner may have a right angle, an obtuse angle, a rounded right angle, or a rounded obtuse angle.

In some embodiments of the present invention, the aforementioned method may further include: after forming the isolation structure: removing the isolation structure on the semiconductor substrate.

In some embodiments of the present invention, removing the isolation structure on the semiconductor substrate may include planarizing and polishing the isolation structure. The aforementioned method may further include: after planarizing and polishing the isolation structure: forming a silicon nitride layer; and etching the silicon nitride layer and the protective layer by performing a patterning process at positions corresponding to the island patterns to form a plurality of via holes. A bottom of each of the via holes may communicate with the corresponding one of the island patterns to form a contact landing area.

Another aspect of the present invention is directed to a method of fabricating a semiconductor device. The method may include: providing a semiconductor substrate; depositing a surface oxide layer, a first silicon nitride layer and a hard mask on the semiconductor substrate; patterning the hard mask to form a patterned hard mask by performing a patterning process; patterning the surface oxide layer to form a patterned liner oxide layer; patterning the first silicon nitride layer to form a patterned silicon nitride layer; forming alternately arranged island patterns and trenches in the semiconductor substrate. A portion of an upper surface of each island pattern close to a corresponding one of the trenches may be a corner area, the patterned hard mask may cover the patterned silicon nitride layer, the patterned silicon nitride layer may cover the patterned liner oxide layer, and the patterned liner oxide layer may cover the island patterns.

The aforementioned method may further include: etching the patterned liner oxide layer and the patterned silicon nitride layer to expose the corner area; forming a protective layer on a sidewall and a bottom surface of each of the trenches, the corner area, a surface of the patterned liner oxide layer, and an etched side surface of the patterned silicon nitride layer. The protective layer may extend from the sidewall of each of the trenches to the upper surface of a corresponding one of the island patterns to form a corner; and forming an isolation structure in the corresponding one of the trenches.

Another aspect of the present invention is directed to a semiconductor device. The device may include: a semiconductor substrate including alternately arranged island patterns and trenches, wherein a portion of an upper surface of each island pattern close to a corresponding one of the trenches may be a corner area; a patterned liner oxide layer covering an area of the upper surface of the island pattern except the corner area; and a protective layer covering a sidewall and a bottom surface of each of the trenches, the corner area, and a side surface of the patterned liner oxide layer; and an isolation structure in the corresponding one of the trenches. The protective layer may extend from the sidewall of each of the trenches to the corner area to form a corner.

In some embodiments of the present invention, each of the island patterns may be an active region in the semiconductor device.

In some embodiments of the present invention, the protective layer may be made of silicon oxide, silicon nitride, silicon oxynitride or silicon carbonitride.

In some embodiments of the present invention, the corner may have an angle of from 90 to 120 degrees.

In some embodiments of the present invention, the corner may have a right angle, an obtuse angle, a rounded right angle or a rounded obtuse angle.

In some embodiments of the present invention, the device may further include: a patterned silicon nitride layer covering the patterned liner oxide layer. An orthographic projection of the patterned silicon nitride layer may be smaller than or equal to an orthographic projection of the patterned liner oxide layer. The protective layer may further cover a surface of the silicon nitride layer.

In some embodiments of the present invention, the corner may have an angle of from 90 to 120 degrees.

In some embodiments of the present invention, the corner may have a right angle, an obtuse angle, a rounded right angle or a rounded obtuse angle.

In some embodiments of the present invention, the device may further include: a patterned silicon nitride layer covering the patterned liner oxide layer. An orthographic projection of the patterned silicon nitride layer may be greater than an orthographic projection of the patterned liner oxide layer. The protective layer may further cover a surface of the silicon nitride layer.

In some embodiments of the present invention, the corner may have an angle of from 90 to 120 degrees.

In some embodiments of the present invention, the corner may have a right angle, an obtuse angle, a rounded right angle or a rounded obtuse angle.

In the semiconductor device and the manufacturing method thereof, the protective layer may extend from the sidewall of the trench to the upper surface of the island pattern to form a corner, so that the upper surface of the island pattern near the trench can be protected by the protective layer. In the subsequent process, an area on the island pattern near the corner may be prevented from being oxidized and become hollowed, causing carrier drop in the semiconductor device channel. Thus, the boundary effect of the island pattern may be suppressed, and, compared with a contact landing area with notches, a larger contact landing area may be provided for subsequent processes.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of the specification, illustrate embodiments of the present invention and together with the specification, serve to explain the principles of the present invention. It is apparent that the drawings in the following description are only some of the embodiments of the present invention, and other drawings may be obtained from those skilled in the art without departing from the drawings.

FIGS. 1, 2, and 3 are schematic diagrams showing the fabrication of a semiconductor device in the related art.

FIG. 4 is a schematic diagram of a semiconductor device in accordance with one embodiment of the present invention.

FIG. 5 is a schematic diagram of a semiconductor device in accordance with one embodiment of the present invention.

FIG. 6 is a schematic diagram of a semiconductor device in accordance with another embodiment of the present invention.

FIG. 7 is a flow chart illustrating a method of fabricating a semiconductor device in accordance with one embodiment of the present invention.

FIG. 8 is a flow chart illustrating steps subsequent to step S704 of FIG. 7 in accordance with one embodiment of the present invention.

FIG. 9 is a flow chart illustrating a method of fabricating a semiconductor device in accordance with another embodiment of the present invention.

FIG. 10 is a flow chart illustrating a method of fabricating a semiconductor device in conjunction with the embodiment shown in FIG. 7 in accordance with one embodiment of the present invention.

FIG. 11 is a cross-sectional view showing the completion of step S1002 in accordance with one embodiment of the present invention.

FIG. 12 is a cross-sectional view showing the completion of step S1003 in accordance with one embodiment of the present invention.

FIG. 13 is a cross-sectional view showing the completion of step S1004 in accordance with one embodiment of the present invention.

FIG. 14 is a cross-sectional view showing the completion of step S1005 in accordance with one embodiment of the present invention.

FIG. 15 is a cross-sectional view showing the completion of step S1006 in accordance with one embodiment of the present invention.

FIG. 16 is a cross-sectional view showing the completion of step S1007 in accordance with one embodiment of the present invention.

FIG. 17 is a cross-sectional view showing the completion of step S1008 in accordance with one embodiment of the present invention.

FIG. 18 is a cross-sectional view showing the completion of step S1009 in accordance with one embodiment of the present invention.

FIG. 19 is a cross-sectional view showing the completion of step S1010 in accordance with one embodiment of the present invention.

FIG. 20 is a cross-sectional view showing the completion of step S1011 in accordance with one embodiment of the present invention.

FIG. 21 is a flow chart illustrating a method of fabricating a semiconductor device in conjunction with the example shown in FIG. 9 in accordance with another embodiment of the present invention.

FIG. 22 is a cross-sectional view showing the completion of step S2104 in accordance with one embodiment of the present invention.

FIG. 23 is a cross-sectional view showing the completion of step S2105 in accordance with one embodiment of the present invention.

### DETAIL DESCRIPTION OF THE EMBODIMENTS

Exemplary embodiments will now be described more fully with reference to the accompanying drawings. However, these exemplary embodiments can be implemented in many forms and should not be construed as being limited to those set forth herein. Rather, these embodiments are presented to provide a full and thorough understanding of the present invention and to fully convey the concepts of the exemplary embodiments to others skilled in the art. In addition, the described features, structures, and characteristics may be combined in any suitable manner in one or more embodiments. In the following detailed description, many specific details are set forth to provide a more thorough understanding of the present invention. However, those skilled in the art will recognize that the various embodiments can be practiced without one or more of the specific details or with other methods, components, materials, or the like. In some instances, well-known solutions are not shown or not described in detail to avoid obscuring aspects of the embodiments.

Further, throughout the drawings, like reference numbers indicate identical or similar elements, so any duplicate description of them will be omitted. The represented blocks in the drawings are purely functional entities, which do not necessarily correspond to physically or logically separate entities. In other words, these functional entities may be implemented as software, or entirely or in part in one or more software-hardened modules, or in different networks and/or processor devices and/or microcontroller devices.

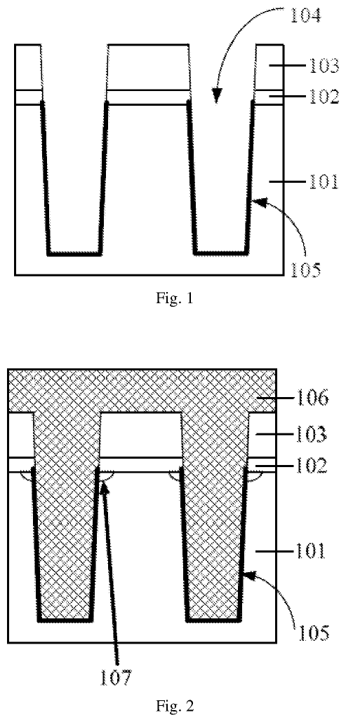

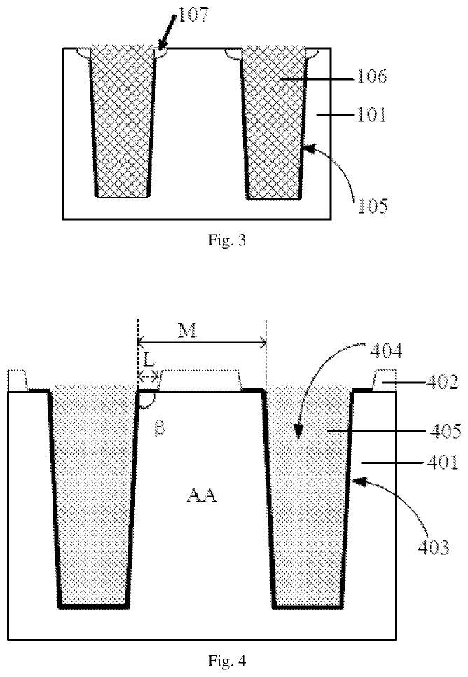

In the related embodiments, FIGS. 1, 2, and 3 illustrate schematic views of the fabrication of a semiconductor device. As shown in FIG. 1, a liner oxide layer 102 and a silicon nitride layer 103 may be sequentially formed on a semiconductor substrate 101. A trench 104 then may be formed in the semiconductor substrate 101, the liner oxide layer 102, and the silicon nitride layer 103 by using a patterned photoresist, and a liner 105 may be formed on the bottom surface and sidewalls of the trench 104. As shown in FIG. 2, the trench 104 may be filled with an isolation material (which may be an oxide such as silicon oxide or a combination of silicon oxide and polysilicon) to form the isolation structure 106. In addition, the semiconductor substrate 101 may be implanted with N-type or P-type ions to form an active region. The active region in the semiconductor substrate 101 may be affected by the oxidation reaction at the corner junction with the liner 105. As shown in FIG. 3, after the liner oxide layer 102 and the silicon nitride layer 103 are removed, a notch 107 may form at a corner of the active region and a portion of the isolation structure near the corner junction. Due to the presence of the notch 107, the number of carriers in the channel may be reduced, which reduces the contact landing area of the active region in subsequent processes.

In the technical solution provided by the present invention, the underlying oxide layer on the active region may be etched such that an upper surface of the active region at the corner becomes exposed, and a subsequently-formed liner may extend to the exposed upper surface of the active region to prevent a notch being formed.

The exemplary embodiments of the present invention will be described in detail below with reference to the accompanying drawings.

FIG. 4 is a schematic view of a semiconductor device in accordance with one embodiment of the present invention.

As shown in FIG. 4, the semiconductor device provided by the present invention may include: a semiconductor substrate 401, a patterned liner oxide layer 402 and a protective layer 403. The semiconductor substrate 401 may include alternately arranged island patterns and trenches 404. The island patterns (indicated by AA in FIG. 4) may be formed by patterning an active region formed by ion implantation in a semiconductor substrate. The upper surface of the island pattern AA near the trench 404 may be a corner area. The patterned liner oxide layer 402 may cover an area of the upper surface of the island pattern except the corner area. The protective layer 403 may cover the sidewall and the bottom surface of each of the trenches 404, the corner area, the island pattern, and the side surface of the patterned liner oxide layer 402. The protective layer 403 may extend from the sidewall of the trench 404 to the upper surface of the island pattern AA to form a corner (indicated by β in FIG. 4).

In some embodiments of the present invention, the semiconductor substrate may be one of a silicon substrate, a gallium nitride, a gallium arsenide and a silicon-on-insulator substrate. The semiconductor substrate may be a P-type substrate or an N-type substrate. An island pattern may be formed by etching the trench, and may be a P well formed on the N-type substrate or an N well formed on the P-type substrate. The type of ions implanted in the island pattern can be selected as needed.

According to some embodiments of the present invention, the patterned liner oxide layer 402 may be further etched after the trench 404 is formed, doing so may, unlike the conventional process, expose a corner area on the upper surface of the island pattern near the trench.

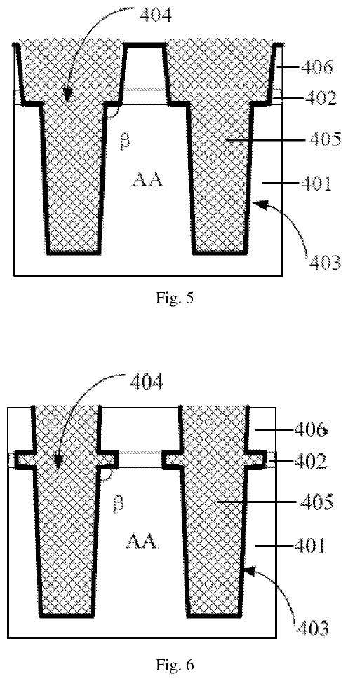

In some embodiments of the present invention, FIG. 5 illustrates a structural diagram of a semiconductor device including, in addition to the structure shown in FIG. 4, a patterned silicon nitride layer 406 overlying the patterned liner oxide layer 402. The orthographic projection of the patterned silicon nitride layer 406 may be smaller than or equal to the orthographic projection of the patterned liner oxide layer 402. The protective layer 403 may also cover the surface, including the side surface and the upper surface, of the patterned silicon nitride layer 406.

In some embodiments of the present invention, FIG. 6 illustrates a structural diagram of a semiconductor device including, in addition to the structure shown in FIG. 4, a patterned silicon nitride layer 406 overlying the patterned liner oxide layer 402. The orthographic projection of the patterned silicon nitride layer 406 may be larger than the orthographic projection of the patterned liner oxide layer 402. The protective layer 403 may also cover the surface, including the side surface and the upper surface, of the patterned silicon nitride layer 406.

In some embodiments of the present invention, the semiconductor device may further include an isolation structure 405 formed by depositing an isolation material over the protective layer 403. The material of the isolation structure 405 may be silicon nitride or silicon oxide or a combination of silicon nitride and silicon oxide.

In some embodiments of the present invention, since all the protective layer may be formed in one single process, the protective layer 403 extending to the upper surface of the island pattern AA may have the same thickness as the protective layer 403 located on the side walls and the bottom surface of the trench 404.

In some embodiments of the present invention, the protective layer 403 may have a thickness in a range of 2 nm to 5 nm.

In some embodiments of the present invention, the protective layer 403 may be made of a material including, but not limited to, silicon oxide, silicon nitride, silicon oxynitride or silicon carbonitride. The protective layer 403 may be formed by methods such as, for example, a chemical vapor deposition method, an atomic layer deposition method, a spin coating method, or other suitable processes, and this invention is not limited in this regard.

In some embodiments of the present invention, the protective layer 403 on the upper corner area of the island pattern AA may have a width of 5-20 nm, so that the protective layer 403 thereon can effectively protect the island pattern on the corner area from being oxidized to form a notch.

In some embodiments of the present invention, the corner β may have an angle in a range of 90 to 120 degrees. The corner β may have a right angle, an obtuse angle, a rounded right angle or a rounded obtuse angle. When the corner β has an obtuse angle, the shape of the trench is an inverted trapezoid, and the side wall of the island pattern AA having a certain inclination angle may advantageously form a protective layer. For example, the corner β may preferably have an angle of 100 to 110 degrees.

In some embodiments of the present invention, the shape of the corner may be a right angle, an obtuse angle, or a rounded right angle or a rounded obtuse angle. That is, the corner β is not limited to the near right angle shape but may be a relatively rounded near-right angle. For example, the angle formed by the upper surface of the island pattern AA and the side wall adjacent to the trench may have a certain chamfering angle, and the specific value of the chamfering radius can be determined as needed.

In the semiconductor device provided in the embodiment of the present invention, a protective layer may extend from the sidewall of the trench to the upper surface of the island pattern to form a corner, so that the corner of the island pattern near the trench can be protected by the protective layer. In the subsequent process, an area on the island pattern near the corner may be prevented from being oxidized and become hollowed, causing the carrier drop in the semiconductor device channel. Thus, the boundary effect of the island pattern may be suppressed, and, compared with a contact landing area with notches, a larger contact landing area may be provided for subsequent processes. In addition, the corner may be an obtuse angle, so that the island pattern may have a certain inclination angle close to the side wall of the channel, which is advantageous for the formation of the protective layer.

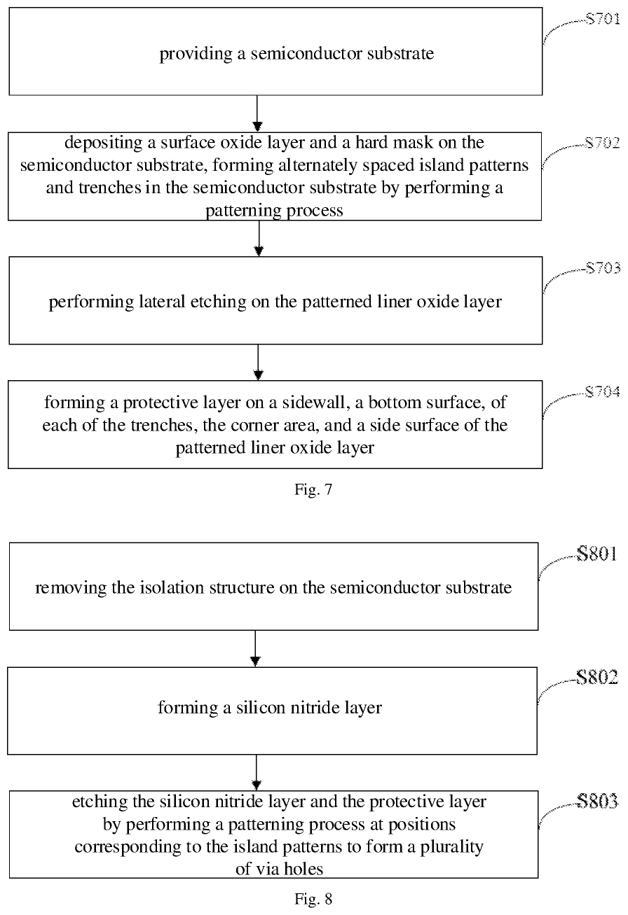

FIG. 7 is a flowchart illustrating a method for fabricating a semiconductor device in accordance with one embodiment of the present invention. As shown in FIG. 7, the method may include the following steps S701 through S704.

In step S701, a semiconductor substrate may be provided.

In step S702, a surface oxide layer and a hard mask may be deposited on the semiconductor substrate, and alternately arranged island patterns and trenches may be formed in the semiconductor substrate by a patterning process. In this step, the hard mask may be patterned into a patterned hard mask by a photolithography process, and then the surface oxide layer may be patterned into a patterned oxide layer by using the patterned hard mask.

The upper surface of the island-shaped pattern near the trench may be a corner area, the patterned hard mask may cover the patterned liner oxide layer, and the patterned liner oxide layer may cover the island pattern.

After the surface oxide layer is formed in this step, the first silicon nitride layer may be further formed. Therefore, the specific fabrication process of step S702 may include the following steps.

First, ion implantation may be performed on the semiconductor substrate to form an active region.

Second, a surface oxide layer and a first silicon nitride layer may be sequentially formed on the semiconductor substrate having the active region.

Then, the hard mask may be patterned to form a patterned hard mask by a patterning process, the surface oxide layer may be patterned to form a patterned liner oxide layer, and a trench may be formed in the semiconductor substrate (semiconductor substrate having an active region). Thus, the island patterns may be separated by trenches in the semiconductor substrate, and the upper surface of the island pattern adjacent to the trench may be the corner area.

The hard mask may be used to transfer the mask pattern to the layers underneath the hard mask (e.g., the surface oxide layer, the first silicon nitride layer, the semiconductor substrate) to form a patterned surface oxide layer (i.e., patterned liner oxide layer), a patterned first silicon nitride layer (i.e., a patterned silicon nitride layer) and a patterned semiconductor substrate (i.e., an island pattern).

In step S703, the patterned liner oxide layer may be laterally etched. The upper surface of the island pattern covered by the patterned liner oxide layer and close to the trench may be exposed by the lateral etching.

In step S704, a protective layer may be formed on the sidewall and the bottom surface of the trench, the corner area, and the side surface of the patterned liner oxide layer. The protective layer may extend from a sidewall of the island pattern to an upper surface of the island pattern to form a corner.

Additionally, the aforementioned method may further include a step S705, in which an isolation structure may be formed in each of the trenches.

It should be noted that, in this step, an isolation material may be deposited in each of the trenches to form an isolation structure. The isolation material may be made of silicon nitride or silicon oxide or a combination of silicon nitride and silicon oxide, and may be formed by a process such as SOD or FCVD.

In some embodiments of the present invention, the corner β may have an angle in a range of 90 to 120 degrees. The corner β may be a right angle, a near right angle or an obtuse angle. When the corner β has an obtuse angle, the shape of the trench is an inverted trapezoid, and the side wall of the island pattern AA having a certain inclination angle can advantageously form a protective layer. For example, the corner β may preferably have an angle of from 100 to 110 degrees.

In some embodiments of the present invention, the corner may have a right angle, an obtuse angle, a rounded right angle or a rounded obtuse angle. That is, the corner β is not limited to the near right angle, but may be a relatively rounded near-right angle. For example, the angle formed by the upper surface of the island pattern AA and the sidewall adjacent to the trench may have a certain chamfering angle, and the specific value of the chamfering radius can be determined as needed.

FIG. 8 shows a flowchart illustrating the formation of the isolation structure of step S705. In some embodiments of the present invention, as shown in FIG. 8, the method may further include, after step S705, the following steps.

In step S801, the isolation structure on the semiconductor substrate may be removed.

The removal of the isolation structure in this step may include: planarizing the isolation structure. Multiple polishing may be performed in this embodiment, and the specific polishing step will be described in detail later.

In step S802, a silicon nitride layer may be formed.

In step S803, the silicon nitride layer and the protective layer may be etched by performing a patterning process at positions corresponding to the island patterns to form a plurality of via holes. A bottom of each of the via holes may communicate with the corresponding one of the island patterns to form a contact landing area.

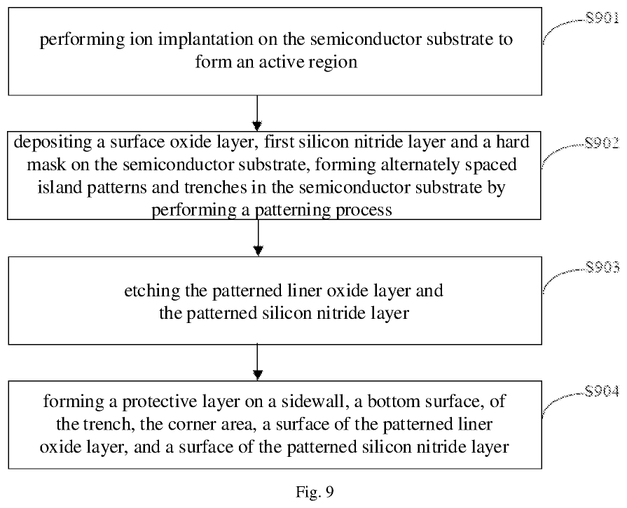

FIG. 9 is a flow chart illustrating a method of fabricating a semiconductor device in accordance with another embodiment of the present invention. As shown in FIG. 9, the method may include the following steps.

In step S901, a semiconductor substrate may be provided.

In step S902, a surface oxide layer, a first silicon nitride layer and a hard mask may be deposited on the semiconductor substrate. Alternately arranged island patterns and trenches may be formed in the semiconductor substrate by a patterning process. In this step, the hard mask may be patterned into a patterned hard mask by a photolithography process, and then the first silicon nitride layer may be formed into a patterned silicon nitride layer by using the patterned hard mask, and the surface oxide layer may be formed into a patterned oxide layer. The upper surface of the island pattern near the trench may be a corner area. The patterned hard mask may cover the patterned silicon nitride layer, the patterned silicon nitride layer may cover the pattern liner oxide layer, and the patterned liner oxide layer may cover the island pattern.

Step S902 may be the same as step S702 shown in FIG. 7. After the surface oxide layer is formed, the first silicon nitride layer may be further formed. Therefore, the specific fabrication process of step S902 may include the following steps.

First, ion implantation may be performed on the semiconductor substrate to form an active region.

Next, a liner oxide layer and a first silicon nitride layer may be sequentially formed on the semiconductor substrate having the active region.

Then, the hard mask may be patterned into a patterned hard mask by a patterning process, the first silicon nitride layer may be patterned into a patterned silicon nitride layer, and the surface oxide layer may be patterned to form a patterned liner oxide layer. A trench may be formed in a semiconductor substrate (the semiconductor substrate having an active region). The island patterns may be separated by trenches in the semiconductor substrate, and the upper surface of the island pattern near the trench may be a corner area.

The hard mask may be used to transfer the mask pattern to the layers under the hard mask (e.g., the surface oxide layer, the first silicon nitride layer, the semiconductor substrate) to form a patterned surface oxide layer (i.e., patterned liner oxide layer), a patterned first silicon nitride layer (i.e., a patterned silicon nitride layer) and a patterned semiconductor substrate (i.e., an island pattern).

As shown in FIG. 9, in step S903, the patterned oxide layer and the patterned silicon nitride layer may be etched to expose the corner areas. In this step, the upper surface of the island pattern can be exposed by etching the liner oxide layer and the first silicon nitride layer on the upper surface of the island pattern near the trench.

In step S904, a protective layer may be formed on a sidewall and a bottom surface of each of the trenches, the corner area, a surface of the patterned liner oxide layer, and a surface of the patterned silicon nitride layer. The protective layer may extend from a sidewall of the island pattern to an upper surface of the island pattern to form a corner.

Additionally, the method may further include a step S905, in which an isolation structure may be formed in each of the trenches.

It should be noted that, in this step, an isolation material may be deposited in the trench to form an isolation structure. The isolation material may be made of silicon nitride or silicon oxide or a combination of silicon nitride and silicon oxide, and may be formed by a process such as SOD or FCVD.

In some embodiments of the present invention, after the isolation structure is formed in step S905, the method may further include the processes shown in FIG. 8. That is, the following steps may be included.

First, the isolation structure on the semiconductor substrate may be removed. The steps to remove the isolation structure may include planarizing and polishing the isolation structure. In this embodiment, multiple polishing processes may be required, and the specific polishing step will be described in detail later.

Second, a second silicon nitride layer may be formed.

Third, the silicon nitride layer and the protective layer may be etched by performing a patterning process at positions corresponding to the island patterns to form a plurality of via holes. A bottom of each of the via holes may communicate with the corresponding one of the island patterns to form a contact landing area.

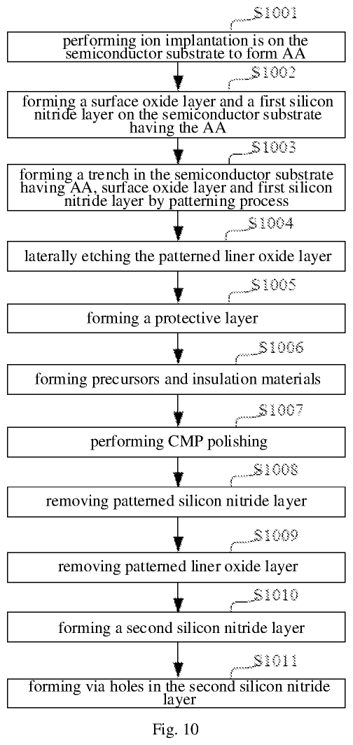

FIG. 10 is a flow chart illustrating a method for fabricating the semiconductor device shown in FIG. 7 with reference to a specific example. Referring to FIG. 10, the method may include the following steps.

In step S1001, ion implantation may be performed on the semiconductor substrate to form an active region (AA). Taking an NMOS transistor as an example, a P well may be formed by ion implantation on an N-type semiconductor substrate. For a PMOS transistor, an N well may be formed by ion implantation on a P-type semiconductor substrate.

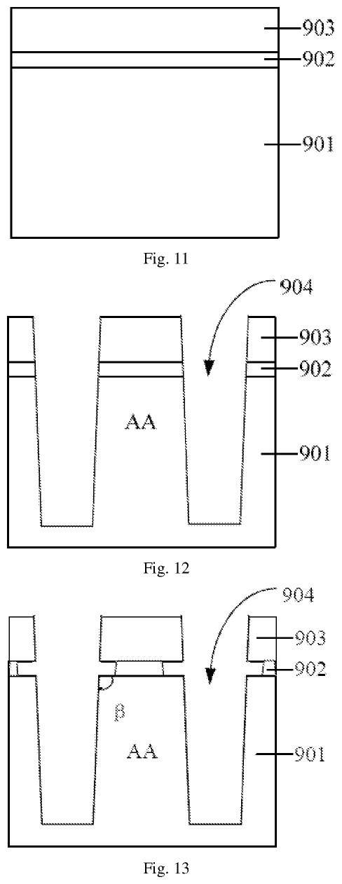

In step S1002, a surface oxide layer and a first silicon nitride layer may be sequentially formed on the semiconductor substrate having the active region. FIG. 11 is a cross-sectional view showing the completion of step S1002, in which a surface oxide layer 902 and a first silicon nitride layer 903 are formed on the semiconductor substrate 901.

In step S1003, a trench may be formed, by a patterning process, in the semiconductor substrate having the active region, the surface oxide layer and the first silicon nitride layer. FIG. 12 is a schematic cross-sectional view showing the completion of step S1003. As shown in FIG. 12, the semiconductor substrate 901, the surface oxide layer 902, and the first silicon nitride layer 903 may be etched (e.g., by a photolithography process) to form a trench 904 in the semiconductor substrate 901. Since the desired ions have been doped in the semiconductor substrate, an alternately arranged island pattern AA and trench 904 may be formed in the semiconductor substrate 901 by a patterning process, and the surface oxide layer 902 may be patterned to form a patterned liner oxide layer. The first silicon nitride layer 903 may be patterned to form a patterned silicon nitride layer.

In step S1004, the patterned liner oxide layer may be laterally etched. After lateral etching, an upper surface of the island pattern partially covered by the patterned oxide layer may be exposed such that an exposed upper surface of the island pattern forms a corner with a sidewall of the trench. FIG. 13 is a schematic cross-sectional view showing the completion of step S1004. As shown in FIG. 13, after lateral etching, the portion of the patterned oxide layer 902 over the island pattern AA adjacent to the trench 904 may be etched by a certain width, and the width may be 5-20 nm. The width of the protective layer on the upper corner area of the island pattern AA may also be 5-20 nm, so that the protective layer can effectively protect the island pattern on the corner area from being oxidized to form a notch.

In addition, the angle of the corner β formed in this step may be in a range from 90 to 120 degrees. The angle of the corner β may be an obtuse angle, so that the shape of the trench is an inverted trapezoid, and the sidewall of the island pattern AA having a certain inclination angle may facilitate the formation of the protective layer in the subsequent step. For example, the angle of the corner β may preferably be in a range of 100 to 110 degrees.

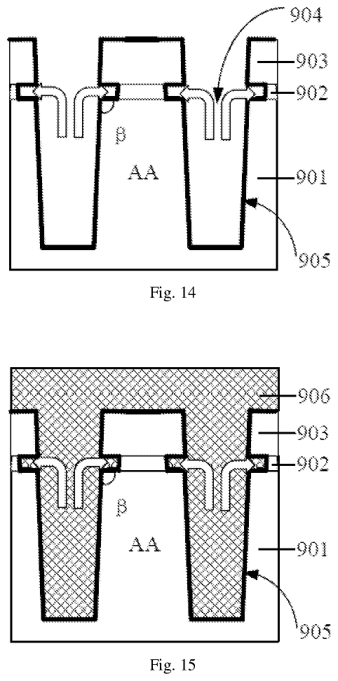

In step S1005, a protective layer may be formed. FIG. 14 is a cross-sectional view after the completion of the step S1005, in which a protective layer 905 may be formed on the sidewall and the bottom surface of the trench 904. In this embodiment, the island pattern may have an exposed region corresponding to the upper surface of the corner. Therefore, the protective layer 905 may also extend to the upper surface of the island pattern at the corner, so that the protective layer 905 may also form a corner (3.

The process used in this step may be Chemical Vapor Deposition (CVD). In addition, the protective layer may also cover the side surfaces of the patterned liner oxide layer and the side surfaces and the upper surface of the patterned silicon nitride layer.

In step S1006, precursors and insulation materials may be formed. FIG. 15 is a cross-sectional view showing the completion of step S1006 in which precursors are formed in the trench 904 of the semiconductor substrate 901, the patterned oxide layer 902, and the patterned silicon nitride layer 903 by a SOD or FCVD process. With the SOD method, the SOD may be post-annealed; if FCVD is used, the UV may be irradiated and then annealed to further fill the trench with the isolation material to form the isolation structure 906. The isolation material may be silicon nitride or silicon oxide or a combination of silicon nitride and silicon oxide.

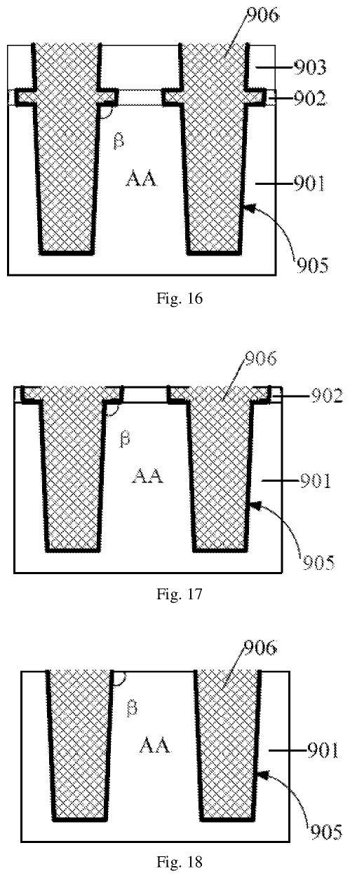

In step S1007, CMP polishing may be performed. FIG. 16 is a schematic cross-sectional view showing the completion of step S1007. Chemical mechanical polishing (CMP) may be conducted to remove the insulation material above the upper surface of the first silicon nitride layer, and the structure shown in FIG. 16 may be obtained.

In step S1008, the patterned silicon nitride layer may be removed. FIG. 17 is a cross-sectional view showing the completion of step S1008. As shown in FIG. 17, the patterned silicon nitride layer 903 may be removed by acid etching or dry etching.

In step S1009, the patterned liner oxide layer may be removed. FIG. 18 is a schematic cross-sectional view showing the completion of step S1009. As shown in FIG. 18, the patterned liner oxide layer 902 may be removed by acid etching.

In this step, the protective layer formed on the upper surface of the island pattern AA at the corner may also be removed, so that the upper surface of the island pattern may become exposed.

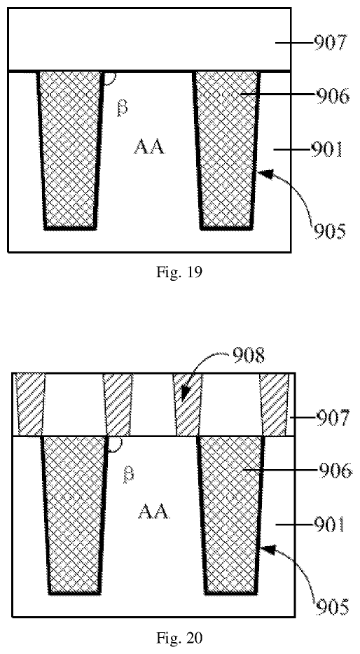

In step S1010, a second silicon nitride layer may be formed. FIG. 19 is a schematic cross-sectional view showing the completion of step S1010. As shown in FIG. 19, a second silicon nitride layer 907 may be formed over the upper surface of the island pattern AA and the isolation structure 906.

In step S1011, a plurality of via holes may be formed in the second silicon nitride layer. FIG. 20 is a schematic cross-sectional view showing the completion of step S1011. As shown in FIG. 20, a second silicon nitride layer 907 may be etched at a position corresponding to the island pattern AA. If a protective layer 905 is provided under the second silicon nitride layer 907, the protective layer 905 may also be etched such that the bottom of the via is in contact with the island pattern AA, such that after the via holes are filled with conductive materials in a subsequent process, they can communicate with the island pattern to form a contact landing area. Due to the protection of the protective layer, no notch is formed on the island pattern at the corners, so, compared with a contact landing area with notches, a larger contact landing area is provided.

Based on the above-mentioned steps S1001 to S1011, it can be seen from the cross-sectional views shown in FIG. 11 to FIG. 20 that before the protective layer of the present invention is formed, the liner oxide layer is laterally etched to expose a portion of the upper surface of the island pattern so that the protective layer can cover the upper surface of the island pattern at the corner. In the subsequent process, an area on the island pattern near the corner may be prevented from being oxidized and become hollowed, causing carrier drop in the semiconductor device channel. Thus, the boundary effect of the island pattern may be suppressed, and, compared with a contact landing area with notches, a larger contact landing area may be provided for subsequent processes.

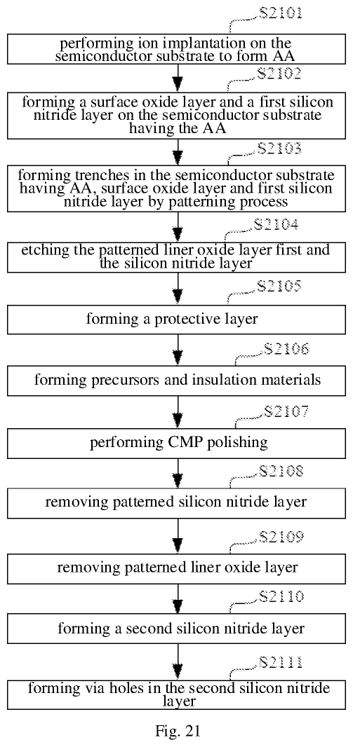

FIG. 21 is a flow chart illustrating a method for fabricating the semiconductor device shown in FIG. 9 with reference to a specific example. As shown in FIG. 21, the method may include the following steps.

In step S2101, ion implantation may be performed on the semiconductor substrate to form an island pattern.

In step S2102, a surface oxide layer and a first silicon nitride layer may be sequentially formed on the semiconductor substrate having the island pattern.

In step S2103, a trench may be formed in the semiconductor substrate having the island pattern, the surface oxide layer, and the first silicon nitride layer by a patterning process. In this step, alternately arranged island patterns and trenches may be formed in a semiconductor substrate by a patterning process, a patterned liner oxide layer may be formed by a patterning process, and a patterned silicon nitride layer may be formed by performing a patterning process on the first silicon nitride layer.

The steps S2101 to S2103 and corresponding cross-sectional views after each of these steps are the same as or similar to those described in steps S801 to S803, and therefore are not repeatedly described herein for the sake of conciseness.

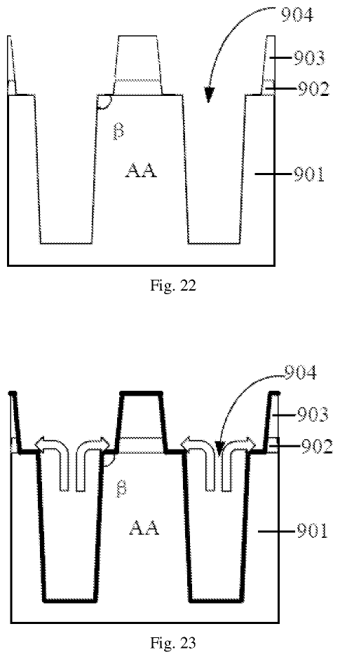

In step S2104, the patterned oxide layer and the patterned silicon nitride layer may be etched. After etching the patterned silicon nitride layer 903 on the side of the island pattern near the trench and the oxide layer 902, a portion of the upper surface of the island pattern covered by the patterned oxide layer may become exposed. The exposed upper surface of the island pattern may form a corner with the sidewall of the trench. FIG. 22 is a schematic cross-sectional view showing the completion of step S2104, which is different from that of FIG. 13 in that the etched oxide layer 902 over the island pattern AA and the portion of the first silicon nitride layer 903 near the trench may be etched. The width of the etching may be 5-20 nm, and the width of the protective layer on the upper corner of the island pattern AA may also be 5-20 nm, so that the protective layer can effectively protect the island pattern at the corner, preventing it from being oxidized to form a notch.

Similarly, the angle of the corner β may range from 90 to 120 degrees. The angle of the corner β may preferably be an obtuse angle such that the shape of the trench is an inverted trapezoid, and the sidewall of the island pattern AA having a certain inclination angle can facilitate the formation of a protective layer in a subsequent step. For example, the angle of the corner β may preferably be in a range of 100 to 110 degrees.

In step S2105, a protective layer may be formed. FIG. 23 is a schematic cross-sectional view showing the completion of step S2105. The protective layer 905 may be formed not only on the sidewalls and the bottom surface of the trench 904, but also on the upper surface of the island pattern at the corner, so that the protective layer 905 forms a corner β. In addition, the protective layer may also cover the etched side surface of the patterned liner oxide layer and the patterned silicon nitride layer and the upper surface of the patterned silicon nitride layer.

The subsequent steps S2106-S2111 and corresponding cross-sectional views after each of these steps are the same as or similar to those described in steps S1006-S1011, and therefore are not repeatedly described herein for the sake of conciseness.

The liner oxide layer and the first silicon nitride layer may be etched to expose a portion of the upper surface of the island pattern before the protective layer is formed, according to the above steps S2101 to S2111. The protective layer may cover the upper surface of the island pattern at the corner.

In summary, in the manufacturing method of the semiconductor device provided by the embodiment, the protective layer may extend from the sidewall of the trench to the upper surface of the island pattern to form a corner, so that the corner area of the upper surface of the island pattern near the trench can be protected by a protective layer. In the subsequent process, an area on the island pattern near the corner may be prevented from being oxidized and become hollowed, causing carrier drop in the semiconductor device channel. Thus, the boundary effect of the island pattern may be suppressed, and, compared with a contact landing area with notches, a larger contact landing area may be provided for subsequent processes. In addition, the corner may have an obtuse angle, so that the island pattern may have a certain inclination angle close to the sidewall of the channel, which is advantageous for the formation of the protective layer.

As will be appreciated by one skilled in the art, aspects of the present invention may be embodied as a system, method or program product. Accordingly, aspects of the present invention may take the form of an entirely hardware embodiment, an entirely software embodiment (including firmware, micro-code, etc.) or an embodiment combining software and hardware aspects that may all generally be referred to herein as a “circuit,” “module” or “system”.

Further, the annexed drawings are merely illustrative of a series of processes included in the method according to exemplary embodiments of the present invention and are not intended to be limiting. It will be readily appreciated that the way in which the processes are illustrated does not indicate any chronological order of them or limit them to a particular chronological order. Furthermore, it will also be readily appreciated that the processes may be performed, for example, synchronously or asynchronously in multiple modules.

Other embodiments of the present disclosure will be apparent to those skilled in the art from considering the specification and practicing the invention disclosed herein. Accordingly, this disclosure is intended to cover all and any variations, uses, or adaptations of the disclosure which follow, in general, the principles thereof and include such departures from the present disclosure as come within common knowledge or customary practice within the art to which the invention pertains. It is also intended that the specification and examples be considered as exemplary only, with true scope and spirit of the disclosure being indicated by the appended claims.

1. A method of fabricating a semiconductor device, comprising:
providing a semiconductor substrate;
depositing a surface oxide layer and a hard mask on the semiconductor substrate;
patterning, by performing a patterning process, the hard mask to form a patterned hard mask;
patterning the surface oxide layer to form a patterned liner oxide layer;
forming alternately arranged island patterns and trenches in the semiconductor substrate, a portion of an upper surface of each island pattern close to a corresponding one of the trenches being a corner area, the patterned liner oxide layer covering the island patterns, and the patterned hard mask covering the patterned liner oxide layer;
performing lateral etching on a side surface of the patterned liner oxide layer to expose the corner area;
forming a protective layer on a sidewall and a bottom surface of each of the trenches, the corner area, and a laterally etched side surface of the patterned liner oxide layer, wherein the protective layer extends from the sidewall of each of the trenches to the upper surface of a corresponding one of the island patterns to form a corner; and
forming an isolation structure in the corresponding one of trenches.

2. The method of claim 1, wherein each of the island patterns is an active region in the semiconductor device.

3. The method of claim 1, wherein the protective layer is made of silicon oxide, silicon nitride, silicon oxynitride or silicon carbonitride.

4. The method of claim 1, wherein the corner has an angle in a range of 90 to 120 degrees.

5. The method of claim 1, wherein the corner has a right angle, an obtuse angle, a rounded right angle, or a rounded obtuse angle.

6. The method of claim 1, further comprising: after forming the isolation structure, removing the isolation structure on the semiconductor substrate.

7. The method of claim 6, wherein removing the isolation structure on the semiconductor substrate comprises:
planarizing and polishing the isolation structure,
and wherein the method further comprises: after planarizing and polishing the isolation structure,
forming a silicon nitride layer; and
etching the silicon nitride layer and the protective layer by performing a patterning process at positions corresponding to the island patterns to form a plurality of via holes, wherein a bottom of each of the via holes communicates with the corresponding one of the island patterns to form a contact landing area.

8. A method of fabricating a semiconductor device, comprising:
providing a semiconductor substrate;
depositing a surface oxide layer, a first silicon nitride layer and a hard mask on the semiconductor substrate;
patterning, by performing a patterning process, the hard mask to form a patterned hard mask;
patterning the surface oxide layer to form a patterned liner oxide layer;
patterning the first silicon nitride layer to form a patterned silicon nitride layer;
forming alternately arranged island patterns and trenches in the semiconductor substrate, a portion of an upper surface of each island pattern close to a corresponding one of the trenches being a corner area, the patterned hard mask covering the patterned silicon nitride layer, the patterned silicon nitride layer covering the patterned liner oxide layer, and the patterned liner oxide layer covering the island patterns;
etching the patterned liner oxide layer and the patterned silicon nitride layer to expose the corner area;
forming a protective layer on a sidewall and a bottom surface of each of the trenches, the corner area, a surface of the patterned liner oxide layer, and an etched side surface of the patterned silicon nitride layer, wherein the protective layer extends from the sidewall of each of the trenches to the upper surface of a corresponding one of the island patterns to form a corner; and
forming an isolation structure in the corresponding one of trenches.

9. A semiconductor device, comprising:
a semiconductor substrate comprising alternately arranged island patterns and trenches, a portion of an upper surface of each island pattern close to a corresponding one of the trenches being a corner area;
a patterned liner oxide layer covering an area of the upper surface of each island pattern except the corner area;
a protective layer covering a sidewall and a bottom surface of each of the trenches, the corner area, and a side surface of the patterned liner oxide layer, wherein the protective layer extends from the sidewall of each of the trenches to the corner area to form a corner; and
an isolation structure in the corresponding one of trenches.

10. The semiconductor device of claim 9, wherein each of the island patterns is an active region in the semiconductor device.

11. The semiconductor device of claim 9, wherein the protective layer is made of silicon oxide, silicon nitride, silicon oxynitride or silicon carbonitride.

12. The semiconductor device of claim 9, wherein the corner has an angle of from 90 to 120 degrees.

13. The semiconductor device of claim 9, wherein the corner has a right angle, an obtuse angle, a rounded right angle, or a rounded obtuse angle.

14. The semiconductor device of claim 9, further comprising:
a patterned silicon nitride layer covering the patterned liner oxide layer, wherein an orthographic projection of the patterned silicon nitride layer is smaller than or equal to an orthographic projection of the patterned liner oxide layer,
and wherein the protective layer further covers a surface of the patterned silicon nitride layer.

15. The semiconductor device of claim 14, wherein the corner has an angle of from 90 to 120 degrees.

16. The semiconductor device of claim 14, wherein the corner has a right angle, an obtuse angle, a rounded right angle, or a rounded obtuse angle.

17. The semiconductor device of claim 9, further comprising:
a patterned silicon nitride layer covering the patterned liner oxide layer, wherein an orthographic projection of the patterned silicon nitride layer is greater than an orthographic projection of the patterned liner oxide layer,
and wherein the protective layer further covers a surface of the silicon nitride layer.

18. The semiconductor device of claim 17, wherein the corner has an angle of from 90 to 120 degrees.

19. The semiconductor device of claim 17, wherein the corner has a right angle, an obtuse angle, a rounded right angle, or a rounded obtuse angle.
